(19) United States
(12) Patent Application Publication
(10) Pub. No.: US 2013/0168696 A1
(43) Pub. Date: Jul. 4, 2013

(54) Silicon Carbide Schottky Diode Device with Mesa Termination and Manufacturing Method Thereof

(71) Applicants: Hui-Hsuan WANG, Taipei (TW); Hao-Chen HUANG, Taipei (TW); Chee-Wee LIU, Taipei (TW)

(72) Inventors: Hui-Hsuan WANG, Taipei (TW); Hao-Chen HUANG, Taipei (TW); Chee-Wee LIU, Taipei (TW)

(73) Assignee: National Taiwan University, Taipei (TW)

(21) Appl. No.: 13/458,926

(22) Filed: Apr. 27, 2012

(30) Foreign Application Priority Data
Jan. 4, 2012 (TW) 101100349

(51) Int. Cl. H01L 29/161; H01L 21/329

(52) U.S. Cl. 257/77; 438/478; 257/E29.084; 257/E21.352

(57) ABSTRACT

A silicon carbide Schottky diode device with mesa terminations and the manufacturing method thereof are provided. The silicon carbide Schottky diode device includes an n-type epitaxial silicon carbide layer with mesa terminations on an n-type silicon carbide substrate, two p-type regions in the n-type epitaxial silicon carbide layer and a Schottky metal contact on the n-type epitaxial silicon carbide layer and the p-type regions, a dielectric layer on sidewalls and planes of the mesa terminations.

### CROSS-REFERENCE TO RELATED APPLICATIONS

The entire contents of Taiwan Patent Application No. 101100349, filed on Jan. 4, 2012, from which this application claims priority, are incorporated herein by reference.

### BACKGROUND OF THE INVENTION

1. Field of the Invention

The present invention relates to a diode device and the manufacturing method thereof, and more particularly to a silicon carbide Schottky diode device with mesa terminations and the manufacturing method thereof.

2. Description of Related Art

Conventional silicon carbide Schottky diode device usually consists of an n-type silicon carbide substrate and an n-type epitaxial silicon carbide layer. Conventional silicon carbide Schottky diode device further consists of Schottky metal contacts formed directly on the n-type epitaxial silicon carbide layer. The Schottky metal contacts are further surrounded by a p-type junction termination extension (JTE) region formed by an ion implantation process. The junction termination extension region is for reducing electric field accumulated at the edge of the junction and to prevent or reduce the interaction between the depletion region and the surface of the device. The surface effect may cause a non-uniform depletion region so as to affect the breakdown voltage of the device.

FIG. 1 show a conventional silicon carbide Schottky P-intrinsic-N (PIN) diode device with junction termination extension region. As shown in FIG. 1, the silicon carbide Schottky PIN diode includes an n-type semiconductor layer 102, a p-type semiconductor layer 104, and two p-type junction termination extension regions 108 on an n-type semiconductor substrate 100 and an anode contact 106. The Schottky PIN diode in FIG. 1 has electric field accumulated at the intersection between the sidewalls of the n-type semiconductor layer 102 and the p-type junction termination extension regions 108 which would degrade the breakdown voltage of the PIN diode. That is, the conventional Schottky diode device shown in FIG. 1 would not be able to sustain a higher voltage without being breakdown when a bias voltage is applied and thus such feature constitutes a limitation for the operation of the conventional Schottky diode device. Therefore, the invention provides a Schottky diode device with mesa terminations so that the Schottky diode device can sustain a relatively higher voltage when a bias voltage is applied to the Schottky diode device.

### SUMMARY OF THE INVENTION

The invention provides a Schottky diode device with mesa terminations so that the Schottky diode device can sustain a relatively higher voltage when a bias voltage is applied to the Schottky diode device.

The achievement of the invention is that the Schottky diode device having a junction termination extension structure with mesas can sustain a higher voltage when the Schottky diode device reaches the breakdown voltage since the depletion region in the n-type semiconductor layer could not extend laterally. Furthermore, the production cost can be reduced because the junction termination extension structure with mesas is beneficial for area utilization. Moreover, the Schottky diode device having a junction termination extension structure with mesas of the invention has a larger on-state current or a smaller on-state resistance comparing to the conventional Schottky diode device when a bias voltage is applied to the Schottky diode device since the metal layer or the n-type doped epitaxial semiconductor layer of the Schottky diode device of the invention have an area larger than that of the conventional Schottky diode device. Furthermore, the Schottky diode device having a junction termination extension structure with mesas of the invention has a larger breakdown voltage comparing to the Schottky diode device with a conventional junction termination extension structure since the depletion region in the n-type semiconductor layer and the n-type semiconductor substrate could not extend laterally to the p-type regions and is confined in the central region of the n-type semiconductor layer when a bias voltage is applied to the Schottky diode device of the invention.

The invention also provides a Schottky diode device comprising an n-type semiconductor substrate, an n-type semiconductor layer having mesas on the n-type semiconductor substrate, two p-type regions in the n-type semiconductor layer, a metal layer on the n-type semiconductor layer and the p-type region, and a dielectric layer on one plane and the sidewall of the mesa, wherein one sidewall of each the p-type region constitutes a portion of a sidewall of the mesa.

The invention also provides a manufacturing method of a Schottky diode device comprising the following steps. First, an n-type semiconductor substrate is provided. Then an n-type semiconductor layer is formed on the n-type semiconductor substrate. Next, two p-type regions are formed in the n-type semiconductor layer. Then a metal layer is formed on the n-type semiconductor layer and the p-type region. Next, the n-type semiconductor layer and the p-type regions are etched to form two mesas on two sides of the n-type semiconductor layer and the p-type regions, wherein one sidewall of each the p-type region constitutes a portion of a sidewall of the mesa. Finally, a dielectric layer is formed on one plane and the sidewall of each the mesa.

### BRIEF DESCRIPTION OF THE DRAWINGS

The concepts and advantages of the invention will be easier to be understood by way of the following detailed description and the accompanying drawings.

FIG. 1 shows a conventional silicon carbide Schottky P-intrinsic-N (PIN) diode device with junction termination extension region.

FIG. 2 shows a cross-sectional view of a Schottky diode device with mesa terminations according to one embodiment of the invention.

FIG. 2A shows an n-type semiconductor layer formed on an n-type semiconductor substrate.

FIG. 2B shows p-type diffusion regions formed in the n-type semiconductor layer by ion implantation process.

FIG. 2C shows a metal layer formed on the n-type semiconductor layer and the p-type regions to form a Schottky contact via deposition and patterning to etch processes.

FIG. 2D shows a junction termination extension structure with mesa formed on the n-type semiconductor layer and the p-type regions via selective etching process.

FIG. 2E shows a dielectric layer formed on the sidewalls and the plane of the mesa.

FIGS. 3A and 3B show schematic views of depletion regions of junction termination extension structure and junction termination extension structure with mesa respectively.

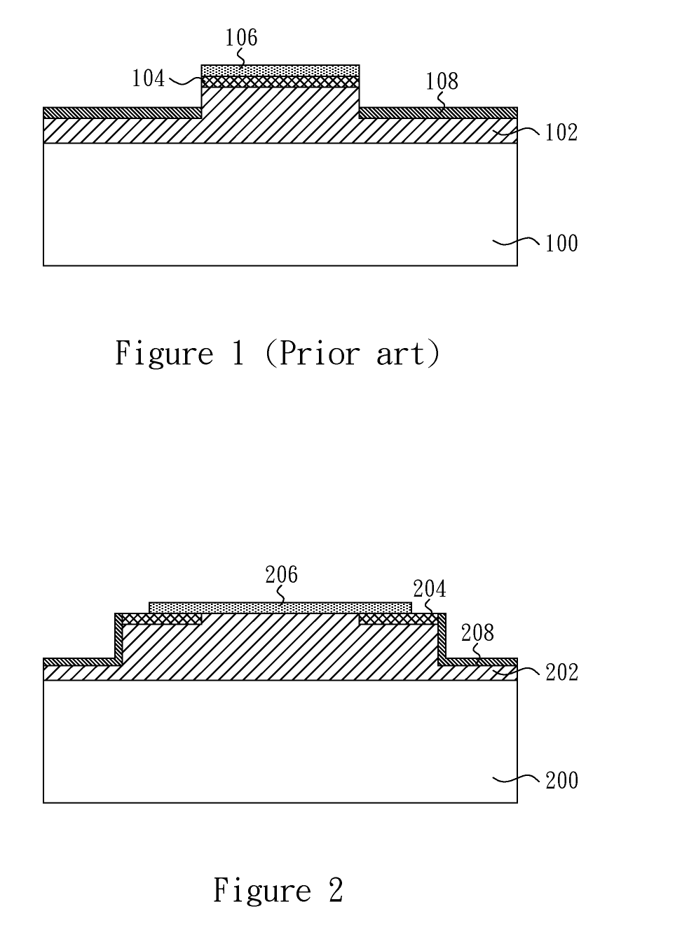

### DETAILED DESCRIPTION OF THE PREFERRED EMBODIMENTS

Various example embodiments of the present invention will now be described more fully with reference to the accompanying drawings in which some example embodiments of the invention are shown. In the drawings, the size of every component may be exaggerated for clarity. Detailed illustrative embodiments of the present invention are disclosed herein. However, specific structural and functional details disclosed herein are merely representative for purposes of describing example embodiments of the present invention. This invention may, however, be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

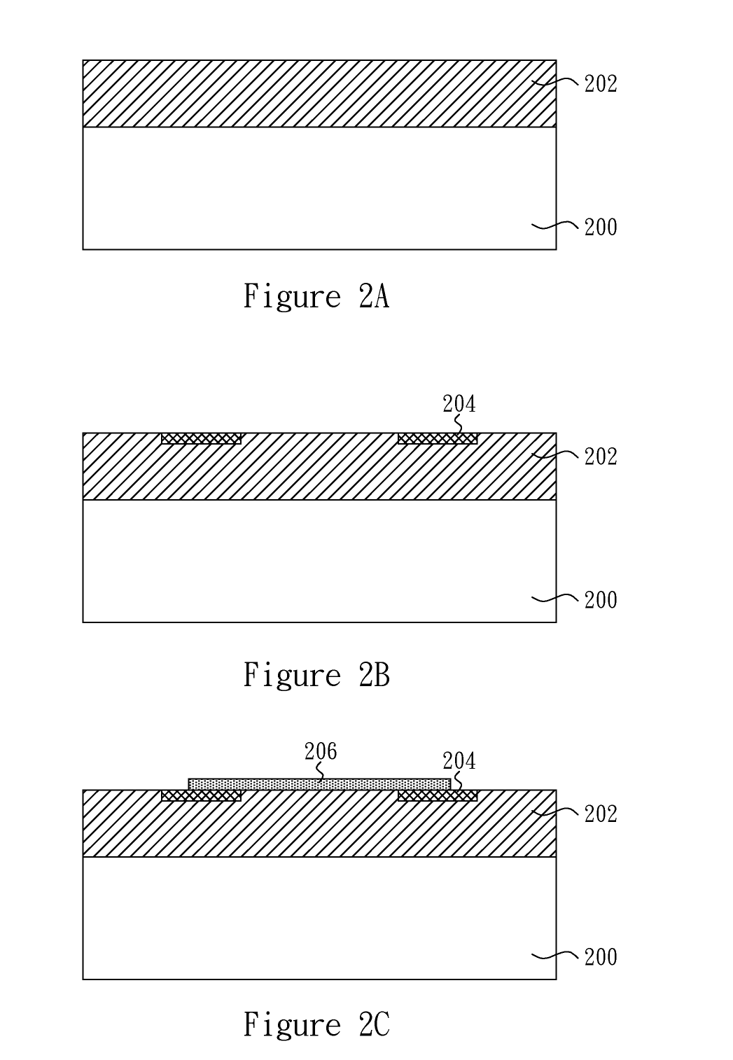

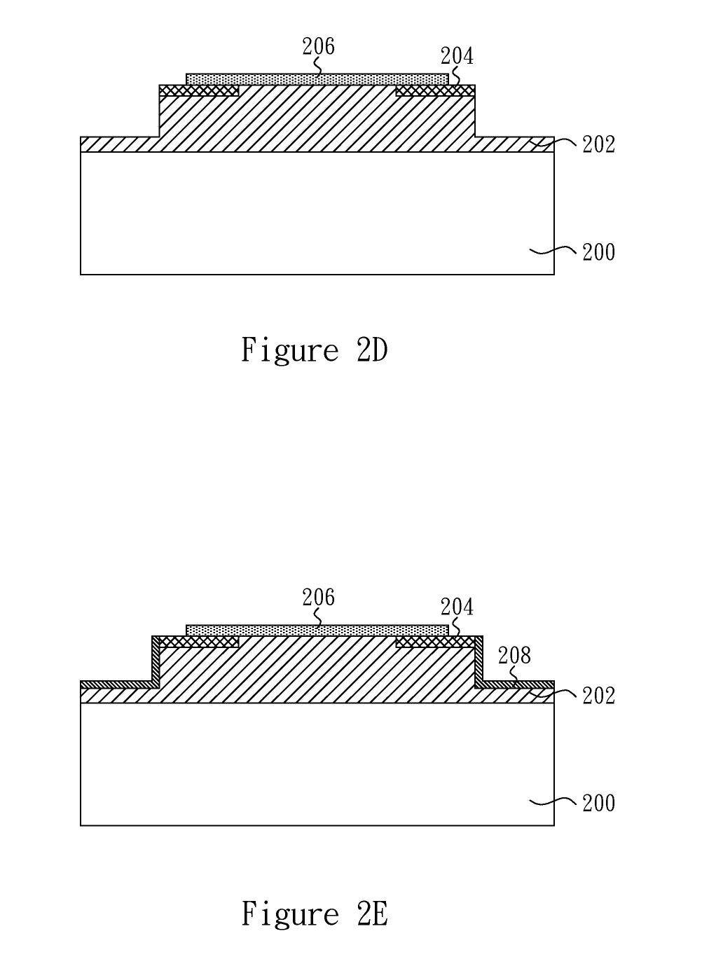

FIG. 2 shows a cross-sectional view of a Schottky diode device with mesa terminations according to one embodiment of the invention. The Schottky diode device with mesa terminations comprises an n-type semiconductor substrate 200, an n-type semiconductor layer 202 on the n-type semiconductor substrate 200, two p-type regions 204 in the n-type semiconductor layer 202 and the sidewalls of the mesa of the n-type semiconductor layer 202, a metal layer 206 on the n-type semiconductor layer 202 and a dielectric layer 208 on the sidewalls of the mesa and the planes of the n-type semiconductor layer 202. The n-type semiconductor substrate 200 comprises, but is not limited to, an n-type doped silicon carbide (SiC) substrate. The n-type semiconductor substrate 200 further comprises other n-type doped silicon-based substrate or a material having an n-type doped silicon substrate. The n-type semiconductor layer 202 includes, but is not limited to, an n-type doped epitaxial silicon carbide layer. The n-type semiconductor layer 202 further includes an n-type doped epitaxial gallium nitride (GaN) layer or a material having an n-type doped epitaxial gallium nitride layer. The n-type epitaxial layer can be formed by any epitaxial growth process in the art. The n-type dopants of the n-type semiconductor substrate 200 and the n-type semiconductor layer 202 include nitrogen, phosphor or arsenic ions. The p-type regions are formed by ion implanting p-type dopants such as aluminum or boron ions into the n-type semiconductor layer 202. The metal layer 206 comprises a Schottky metal layer and the dielectric layer 208 includes aluminum oxide (Al₂O₃) or silicon dioxide (SiO₂).

FIGS. 2A to 2E show the manufacturing method of a silicon carbide Schottky diode device with mesa terminations according to one embodiment of the invention. As shown in FIG. 2A, an n-type semiconductor layer 202 is formed on an n-type semiconductor substrate 200. The n-type semiconductor substrate 200 includes a silicon carbide substrate with n-type dopants. The concentration of the dopants of the n-type semiconductor substrate 200 is about 5×10¹⁸ cm⁻³. The n-type semiconductor layer 202 comprises an epitaxial silicon carbide layer with n-type dopants and can be formed by any suitable epitaxial growth process such as chemical vapor deposition, molecular beam epitaxy (MBE) and sublimation methods. The concentration of the dopants of the n-type semiconductor layer 202 is about 6×10¹⁵ cm⁻³. The doped silicon carbide layer can be formed by doping in situ during the growth process of the epitaxial layer so that the dopants can be formed in and mixed with silicon carbide while the epitaxial layer is formed. The thickness of the n-type epitaxial layer is about 10 μm. The n-type dopants comprise V group elements including nitrogen, phosphor and arsenic ions. The concentration of the p-type dopants is about 5×10¹⁶ cm⁻³.

FIG. 2B shows p-type diffusion regions 204 formed in the n-type semiconductor layer 202 by ion implantation process. The p-type diffusion regions 204 are formed through ion implanting the n-type semiconductor layer 202 to implant p-type dopants such as aluminum or boron ions with a reticle having a pattern of the p-type regions as a mask. The thickness of the p-type region is about 1.6 μm and the concentration of the dopants of the p-type dopants is about 5×10¹⁶ cm⁻³.

FIG. 2C shows a metal layer 206 formed on the n-type semiconductor layer 202 and the p-type regions 204 to form a Schottky contact via deposition and patterning to etch processes. The metal layer 206 comprises gold, platinum, aluminum and silver, etc. FIG. 2D shows a junction termination extension structure with mesa formed on the n-type semiconductor layer 202 and the p-type regions 204 via selective etching process. The junction termination extension structure with mesa is formed by selectively etching the n-type semiconductor layer 202 and portions of the p-type regions 204 through a reticle. In one embodiment, if the thickness of the n-type epitaxial layer is about 10 μm, the height of the junction termination extension structure with mesa or the distance between the plane of the mesa and the surface of the n-type epitaxial layer is about 6 μm. FIG. 2E shows a dielectric layer 208 formed on the sidewalls and the plane of the mesa. The dielectric layer 208 comprises aluminum oxide or silicon dioxide which can be formed by any suitable process such as thermal oxidation method.

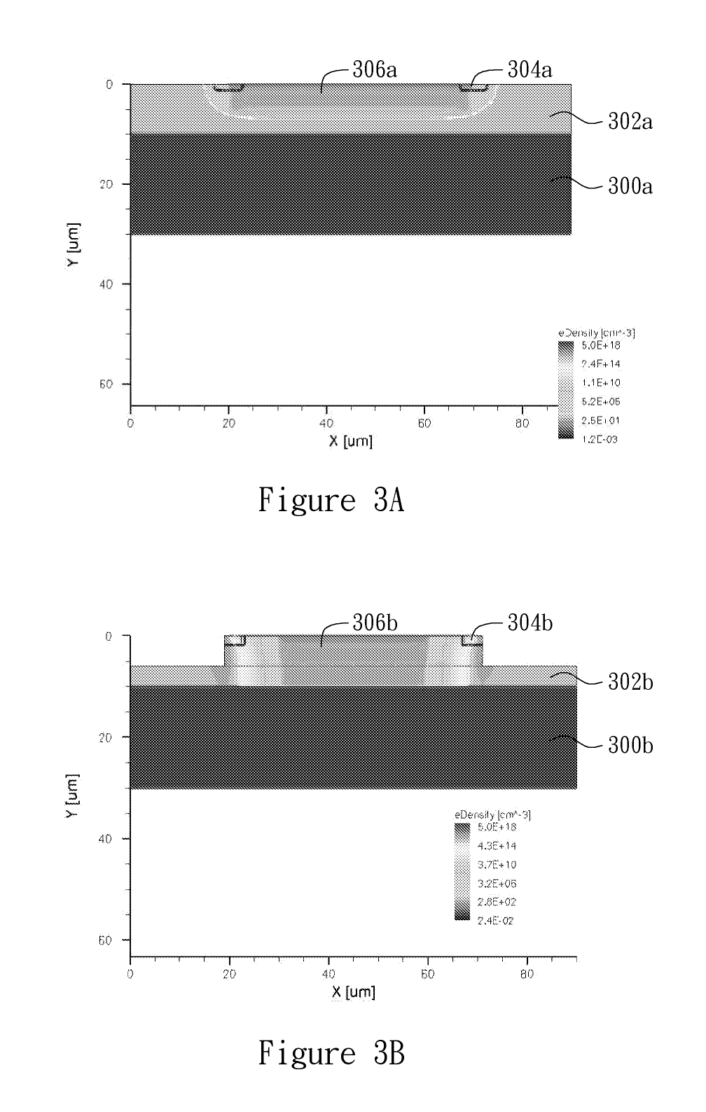

FIGS. 3A and 3B show schematic views of depletion regions of junction termination extension structure and junction termination extension structure with mesa respectively. As shown in FIG. 3A, depletion region 306a in the n-type semiconductor layer 302a and the n-type semiconductor substrate 300a noticeably extends laterally even to the region beneath the p-type regions 304a when a bias voltage is applied to the Schottky diode device. Contrary to the depletion region of the junction termination extension structure shown in FIG. 3A, as shown in FIG. 3B, depletion region 306b in the n-type semiconductor layer 302b and the n-type semiconductor substrate 300b could not extend laterally to the p-type regions 304b and is confined in the central region of the n-type semiconductor layer 302b when a bias voltage is applied to the Schottky diode device. Comparing the depletion regions of FIGS. 3A and 3B, the Schottky diode device having a junction termination extension structure with mesa can sustain a higher voltage when the Schottky diode device reaches the breakdown voltage since the depletion region in the n-type semiconductor layer of the Schottky diode device having a junction termination extension structure with mesa could not extend laterally. While the depletion region in the n-type semiconductor layer of the Schottky diode device without a junction termination extension structure with mesa noticeably extends laterally comparing to that of the Schottky diode device of FIG. 3A.

Although the present invention has been explained in relation to its preferred embodiment, it is to be understood that other modifications and variations can be made without departing from the spirit and scope of the invention as hereafter claimed.

What is claimed is:

1. A semiconductor device, comprising:
an n-type semiconductor substrate;
an n-type semiconductor layer having mesas on the n-type semiconductor substrate;
two p-type regions in the n-type semiconductor layer, one sidewall of each the p-type region constituting a portion of a sidewall of the mesa;
a metal layer on the n-type semiconductor layer and the p-type region; and
a dielectric layer on one plane and the sidewall of each the mesa.

2. The semiconductor device according to claim 1, wherein the semiconductor substrate comprises an n-type doped silicon carbide substrate.

3. The semiconductor device according to claim 2, wherein the concentration of the dopants is about 5×10¹⁸ cm⁻³.

4. The semiconductor device according to claim 1, wherein the semiconductor substrate comprises an n-type doped silicon substrate.

5. The semiconductor device according to claim 1, wherein the n-type semiconductor layer comprises an n-type doped epitaxial silicon carbide layer.

6. The semiconductor device according to claim 5, wherein the concentration of the dopants is about 6×10¹⁵ cm⁻³.

7. The semiconductor device according to claim 5, wherein the thickness of the n-type epitaxial layer is about 10 μm.

8. The semiconductor device according to claim 1, wherein the n-type semiconductor layer comprises an n-type doped epitaxial gallium nitride layer.

9. The semiconductor device according to claim 1, wherein the n-type dopant comprises at least one of nitrogen, phosphor or arsenic ion.

10. The semiconductor device according to claim 7, wherein the distance between the plane of the mesa and the surface of the n-type epitaxial layer is about 6 μm.

11. The semiconductor device according to claim 1, wherein the thickness of the p-type region is about 1.6 μm.

12. The semiconductor device according to claim 1, wherein the p-type dopant comprises at least one of aluminum or boron ion.

13. A manufacturing method of a semiconductor device, comprising:
providing an n-type semiconductor substrate;
forming an n-type semiconductor layer on the n-type semiconductor substrate;
forming two p-type regions in the n-type semiconductor layer;
forming a metal layer on the n-type semiconductor layer and the p-type region;
etching the n-type semiconductor layer and the p-type regions to form two mesas on two sides of the n-type semiconductor layer and the p-type regions, wherein one sidewall of each the p-type region constitutes a portion of a sidewall of the mesa; and
forming a dielectric layer on one plane and the sidewall of each the mesa.

14. The method according to claim 13, wherein the n-type semiconductor substrate comprises an n-type doped silicon carbide substrate.

15. The method according to claim 14, wherein the concentration of the dopants is about 5×10¹⁸ cm⁻³.

16. The method according to claim 13, wherein the n-type semiconductor layer comprises an n-type doped epitaxial silicon carbide layer.

17. The method according to claim 16, wherein the concentration of the dopants is about 6×10¹⁵ cm⁻³.

18. The method according to claim 16, wherein the thickness of the n-type epitaxial layer is about 10 μm.

19. The method according to claim 13, wherein the n-type semiconductor layer comprises an n-type doped epitaxial gallium nitride layer.

20. The method according to claim 16, wherein the distance between the plane of the mesa and the surface of the n-type epitaxial layer is about 6 μm.

21. The method according to claim 13, wherein the thickness of the p-type region is about 1.6 μm.
